(19) United States
(12) Patent Application Publication
(10) Pub. No.: US 2026/0156797 A1
(43) Pub. Date: Jun. 4, 2026

(54) NP BOUNDARY TUNING FOR NANORIBBON-BASED TRANSISTORS

(71) Applicants: Tao Chu, Portland, OR (US); Tahir Ghani, Portland, OR (US); Chia-Ching Lin, Portland, OR (US); Yanbin Luo, Portland, OR (US); Yusung Kim, Portland, OR (US); Chen-Yi Su, Portland, OR (US); Yang Zhang, Rio Rancho, NM (US); Chung-Hsun Lin, Portland, OR (US); Brian Greene, Portland, OR (US); Guowei Xu, Portland, OR (US); Robin Chao, Portland, OR (US); Feng Zhang, Portland, OR (US); Ting-Hsiang Hung, Beaverton, OR (US); Kan Zhang, Hillsboro, OR (US); Chun Wing Yeung, Portland, OR (US); Jiun-hong Lai, Portland, OR (US); Qiwen Wang, Portland, OR (US); Dmitrii Khokhriakov, Hillsboro, OR (US)

(72) Inventors: Tao Chu, Portland, OR (US); Tahir Ghani, Portland, OR (US); Chia-Ching Lin, Portland, OR (US); Yanbin Luo, Portland, OR (US); Yusung Kim, Portland, OR (US); Chen-Yi Su, Portland, OR (US); Yang Zhang, Rio Rancho, NM (US); Chung-Hsun Lin, Portland, OR (US); Brian Greene, Portland, OR (US); Guowei Xu, Portland, OR (US); Robin Chao, Portland, OR (US); Feng Zhang, Portland, OR (US); Ting-Hsiang Hung, Beaverton, OR (US); Kan Zhang, Hillsboro, OR (US); Chun Wing Yeung, Portland, OR (US); Jiun-hong Lai, Portland, OR (US); Qiwen Wang, Portland, OR (US); Dmitrii Khokhriakov, Hillsboro, OR (US)

(21) Appl. No.: 18/966,563

(22) Filed: Dec. 3, 2024

(51) Int. Cl. H10B 10/00

(52) U.S. Cl. CPC H10B 10/125

(57) ABSTRACT

Techniques for tuning the NP boundary between the gate electrode materials of NMOS and PMOS transistors so that the NP boundary is closer to the PMOS transistor can enable the fabrication of a PMOS transistor that is weaker than the adjacent NMOS transistor. In one example, an IC structure includes a first nanoribbon stack and a second nanoribbon stack adjacent to the first nanoribbon stack, a first gate electrode material (e.g., including an N-type work function metal) at least partially around nanoribbons of the first stack and a second gate electrode material (e.g., including a P-type work function metal) at least partially around the nanoribbons of the second stack, where a boundary between the first gate electrode material and the second gate electrode material is closer to the second nanoribbon stack than the first nanoribbon stack.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIG. 2 is an electric circuit diagram of an example 6-transistor (6T) memory cell, according to some embodiments of the present disclosure.

FIG. 3 is a flow diagram of an example method for fabricating an IC structure, where the method includes NP boundary tuning, in accordance with some embodiments.

FIGS. 4-10 provide cross-sectional side views at various stages in the fabrication of an example IC structure according to the method of FIG. 2, in accordance with some embodiments.

FIG. 11 is a top view of a wafer and dies that may include any of the IC structures disclosed herein, in accordance with any of the embodiments disclosed herein.

FIG. 12 is a side, cross-sectional view of an IC device that may include any of the IC structures disclosed herein, in accordance with any of the embodiments disclosed herein.

FIG. 13 is a side, cross-sectional view of an IC package that may include any of the IC structures disclosed herein, in accordance with various embodiments.

FIG. 14 is a side, cross-sectional view of an IC device assembly that may include any of the IC structures disclosed herein, in accordance with any of the embodiments disclosed herein.

FIG. 15 is a block diagram of an example electrical device that may include any of the IC structures disclosed herein, in accordance with any of the embodiments disclosed herein.

### DETAILED DESCRIPTION

Disclosed herein are NP boundary tuning techniques for nanoribbon-based transistors. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating fabrication of nanoribbon-based transistors in which NP boundary tuning techniques may be used, as described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

Nanoribbon-based transistors may be particularly advantageous for continued scaling of metal-oxide-semiconductor (MOS) technology nodes due to the potential to form gates on all four sides of a channel material (hence, such transistors are sometimes referred to as “gate all around” transistors). As used herein, the term “nanoribbon” refers to an elongated structure of a semiconductor material having a longitudinal axis parallel to a support structure (e.g., a substrate, a die, a chip, or a wafer; also referred to herein as, simply, “support”) over which such a structure is built. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon-based transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain (S/D) regions of a transistor provided on either side of the channel material.

Typically, nanoribbon-based transistor arrangements include stacks of nanoribbons, where each stack includes two or more nanoribbons stacked above one another, with a single gate stack that includes a gate electrode material (also known as the metal gate) provided for an entire stack or multiple stacks. Optionally, the gate stack may also include a gate dielectric material around one or more channel regions of each nanoribbon.

Many such nanoribbon-based transistors may be interconnected to implement logic and/or memory circuitry, including complementary MOS (CMOS) circuitry in which both N-type MOS (NMOS) and P-type MOS (PMOS) transistors are implemented over the same support. Implementing stacks of nanoribbons that form basis for future NMOS transistors (such nanoribbons and stacks referred to in the following as, respectively, “NMOS nanoribbons” and “NMOS stacks”) on the same support as stacks of nanoribbons that form basis for future PMOS transistors (such nanoribbons and stacks referred to in the following as, respectively, “PMOS nanoribbons” and “PMOS stacks”) may be accomplished with a number of techniques. One technique for forming both NMOS and PMOS transistors on the same support is to form the gate stacks for NMOS and PMOS transistors from different materials. For example, the gate stack for an NMOS transistor may include one or more N-type work function metals and the gate stack for a PMOS transistor may include one or more P-type work function metals. One example of a CMOS circuit is a static random-access memory (SRAM) circuit, which may be implemented with NMOS pass gate and pull-down transistors and PMOS pull-up transistors.

In SRAM circuit design, the pull-down (PD) transistors are typically stronger than the pass gate (PG) transistors to enable a read access, and the PG transistors are typically stronger than the pull-up (PU) transistors to enable a write access. Thus, PU transistors that are much weaker (e.g., 20-30% weaker) than the PD transistors are typically used to ensure read and write stability in the SRAM circuit. A transistor may be considered “weaker” relative to another transistor if the weaker transistor has a higher threshold voltage (VT), lower current flow, and/or slower switching speed than the stronger transistor. The strength of a nanoribbon-based transistor may be based on a number of factors. One factor that influences the strength of a nanoribbon-based transistor is the width of the nanoribbon(s), where the width of a nanoribbon is a dimension of the nanoribbon in a plane that is substantially parallel with the nanoribbon and orthogonal to the length of the nanoribbon. For example, a smaller nanoribbon width may result in a weaker transistor, and a larger nanoribbon width may result in a stronger transistor. Therefore, an SRAM circuit may be implemented using NMOS PD and PG transistors in wider nanoribbon stacks than PMOS PU transistors. The trend towards smaller transistor sizes can result in challenges in fabricating such PMOS transistors in narrow nanoribbon stacks. Thus, while it may be possible to continue scaling the relatively stronger transistors to smaller sizes, the extent to which weaker transistors may be scaled down by reducing the width of the nanoribbons a corresponding amount may be limited by process, yield, and reliability challenges.

In contrast to conventional techniques modulating transistor strength, tuning the NP boundary between the gate electrode materials of NMOS and PMOS transistors so that the NP boundary is closer to the PMOS transistor can enable the fabrication of a PMOS transistor that is weaker than the adjacent NMOS transistor. In one example, an IC structure includes a first nanoribbon stack and a second nanoribbon stack adjacent to the first nanoribbon stack, a first gate electrode material (e.g., including an N-type work function metal) at least partially around nanoribbons of the first stack and a second gate electrode material (e.g., including a P-type work function metal) at least partially around the nanoribbons of the second stack, where a boundary between the first gate electrode material and the second gate electrode material is closer to the second nanoribbon stack than the first nanoribbon stack.

IC structures as described herein, in particular IC structures fabricated using NP boundary tuning techniques as described herein, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures fabricated using NP boundary tuning techniques as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc. ; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices (e.g., physically coupled, conductively coupled, e.g., directly electrically connected). A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

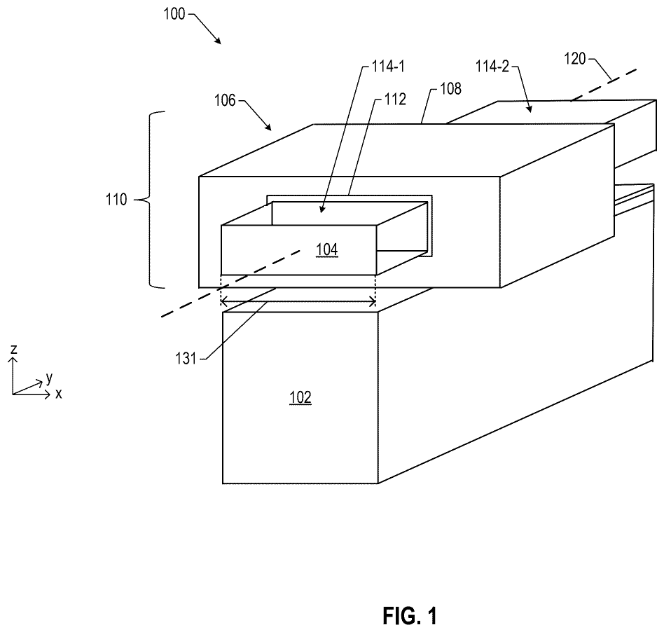

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2 (referred to herein as simply “S/D regions 114”), on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

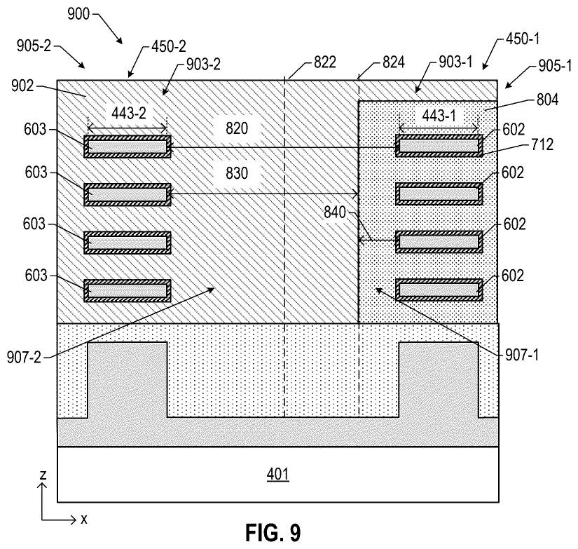

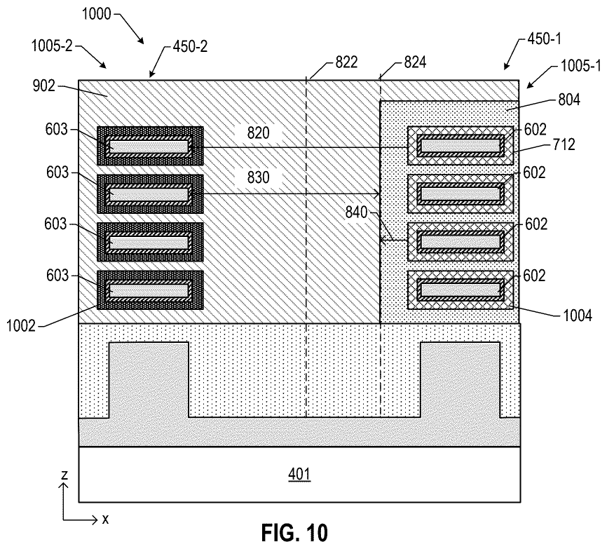

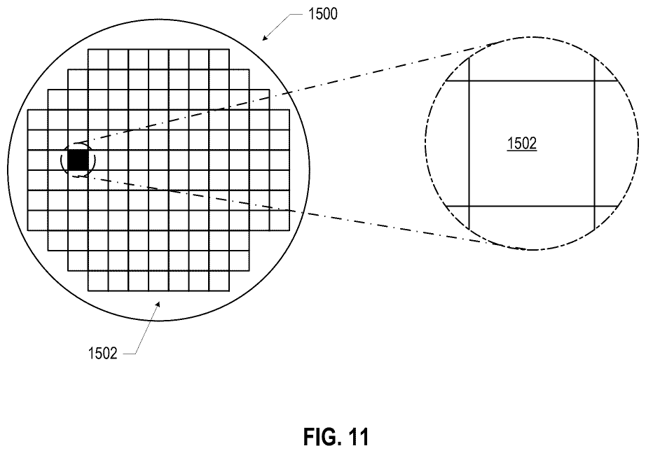

Implementations of the present disclosure may be formed or carried out on any suitable support 102, such as a substrate, a die, a wafer, or a chip. The support 102 may, e.g., be the wafer 1500 of FIG. 11, discussed below, and may be, or be included in, a die, e.g., the singulated die 1502 of FIG. 11, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure fabricated using NP boundary tuning techniques as described herein as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. For example, FIGS. 9 and 10 shows IC structures that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width 131 of the nanoribbon 104 (i.e., a dimension measured in a plane parallel to the support 102 and in a direction perpendicular to the longitudinal axis 120 of the nanoribbon 104, e.g., along the x-axis of the coordinate system) may be at least about 3 times larger than a height or thickness of the nanoribbon 104 (i.e., a dimension measured in a plane perpendicular to the support 102, e.g., along the z-axis of the coordinate system), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an NMOS transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a PMOS transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some examples, nanoribbons of the same semiconductor material may be used to form NMOS and PMOS transistors. In such examples, the NMOS and PMOS transistors may be differentiated by depositing N-type or P-type work function metals around channel portions of those transistors.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, tungsten, ruthenium, palladium, platinum, cobalt, nickel, and conductive metal oxides (e.g., ruthenium oxide), conductive metal nitrides (e.g., titanium nitride). For an NMOS transistor, gate electrode materials that may be used in different portions of the gate electrode material 108 include, but are not limited to, tungsten, hafnium, zirconium, titanium, tantalum, aluminum, alloys of these metals, and carbides of these metals (e.g., hafnium carbide, zirconium carbide, titanium carbide, tantalum carbide, and aluminum carbide, titanium aluminum carbide). In one example in which both an NMOS transistor and PMOS transistor include gate electrode materials that include tungsten, the gate electrode material including tungsten for the NMOS transistor may include fluorine, and the gate electrode material including tungsten for the PMOS transistor may be fluorine-free (e.g., fluorine may be substantially absent from a gate electrode material including tungsten for a PMOS transistor). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided below.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. The channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

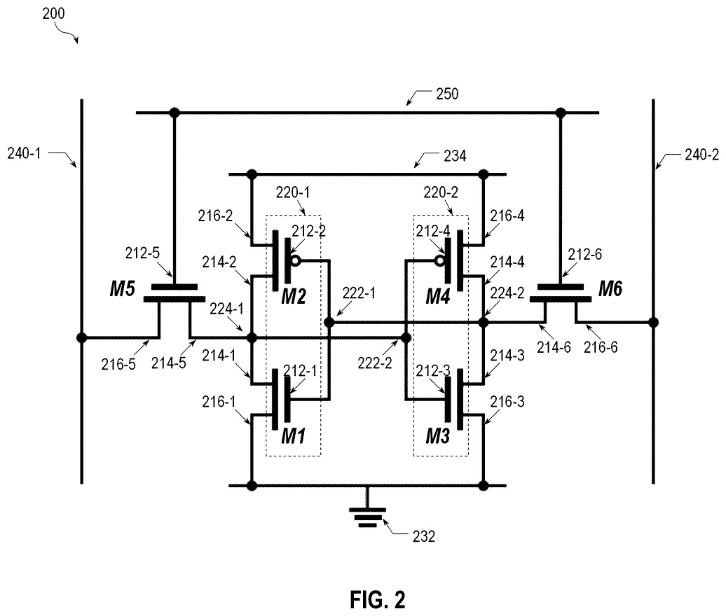

FIG. 2 is an electric circuit diagram of an example 6-transistor (6T) memory cell that may be implemented using nanoribbon-based transistors fabricated using NP boundary tuning techniques as described herein, according to some embodiments of the present disclosure. The SRAM memory cell 200 includes transistors M1-M4 for storing a bit value or a memory state (e.g., logic “1” or “0”) of the cell, and two access transistors, M5 and M6, for controlling access to the cell (e.g., access to write information to the cell or access to read information from the SRAM cell 200). In the example illustrated in FIG. 2, the transistors M2 and M4 are PMOS PU transistors, the transistors M1 and M3 are NMOS PD transistors, and the transistors M5 and M6 are NMOS PG transistors. Each of the transistors M1-M6 may have any transistor architecture (e.g., planar or non-planar, FinFET, nanoribbon/nanowire, etc.). For example, the transistors M1-M6 may have the transistor architecture shown in FIG. 1.

In the SRAM cell 200, each bit may be stored on four transistors (M1, M2, M3, M4) that form two cross-coupled inverters 220-1 and 220-2, each having an input (e.g., inputs 222-1, 222-2) and an output (e.g., outputs 224-1, 224-2). The first inverter 220-1 may be formed by an NMOS transistor M1 and a PMOS transistor M2, while the second inverter 220-2 may be formed by an NMOS transistor M3 and a PMOS transistor M4. As shown in FIG. 2, the gate terminal 212-1 (which may also be referred to as a gate stack, gate structure, or gate) of the transistor M1 may be coupled to the gate terminal 212-2 of the transistor M2, and both of these gate terminals may be coupled to the input 222-1 of the first inverter 220-1. On the other hand, the first S/D terminal 214-1 (which may also be referred to as an S/D region, or source/drain) of the transistor M1 may be coupled to the first S/D terminal 214-2 of the transistor M2, and both of these first S/D terminals 214-1 and 214-2 may be coupled to the output 224-1 of the first inverter 220-1. Similarly, for the second inverter 220-2, the gate terminal 212-3 of the transistor M3 may be coupled to the gate terminal 212-4 of the transistor M4, and both of these gate terminals 212-3, 212-4 may be coupled to the input 222-2 of the second inverter 220-2, while the first S/D terminal 214-3 of the transistor M3 may be coupled to the first S/D terminal 214-4 of the transistor M4, and both of these first S/D terminals 214-3 and 214-4 may be coupled to the output 224-2 of the second inverter 220-2. As also shown in FIG. 2, when the transistors M1 and M3 are NMOS transistors and when the transistors M2 and M4 are PMOS transistors as illustrated in FIG. 2, the second S/D terminals 216-1 and 216-3 of the transistors M1 and M3 may be coupled to a ground voltage 232 (which may also be referred to as ground), while the second S/D terminals 216-2 and 216-4 of the transistors M2 and M4 may be coupled to a supply voltage 234, e.g., VDD (which may also be referred to as a power source, voltage source, current source, etc.). In the embodiments of the SRAM cell 200 where the NMOS transistors shown in FIG. 2 are replaced with PMOS transistors and vice versa, the designation of the ground voltage 232 and the supply voltage 234 would be reversed as well, all of which embodiments being within the scope of the present disclosure.

The four transistors M1-M4 in such configuration form a stable storage cell for storing a bit value of 0 or 1. As further shown in FIG. 2, two additional access transistors, M5 and M6, may serve to control the access to the storage cell of the transistors M1-M4 during read and write operations. As shown in FIG. 2, the first S/D terminal 214-5 of the access transistor M5 may be coupled to the output 224-1 of the first inverter 220-1. Phrased differently, the first S/D terminal 214-5 of the access transistor M5 may be coupled to each of the first S/D terminal 214-1 of the transistor M1 and the first S/D terminal 214-2 of the transistor M2. The second S/D terminal 216-5 of the access transistor M5 may be coupled to a first bitline (BL) 240-1. Thus, each of the first S/D terminal 214-1 of the transistor M1 and the first S/D terminal 214-2 of the transistor M2 may be coupled to the first BL 240-1 (e.g., via the access transistor M5). The gate terminal 212-5 of the access transistor M5 may be coupled to a WL 250.

As further shown in FIG. 2, the first S/D terminal 214-6 of the access transistor M6 may be coupled to the output 224-2 of the second inverter 220-2. Phrased differently, the first S/D terminal 214-6 of the access transistor M6 may be coupled to each of the first S/D terminal 214-3 of the transistor M3 and the first S/D terminal 214-4 of the transistor M4. The second S/D terminal 216-6 of the access transistor M6 may be coupled to a second BL 240-2. Thus, each of the first S/D terminal 214-3 of the transistor M3 and the first S/D terminal 214-4 of the transistor M4 may be coupled to the second BL 240-2 (e.g., via the access transistor M6). The gate terminal 212-6 of the access transistor M6 may be coupled to the WL 250. Thus, the gate terminals 212-5 and 212-6 of both of the access transistors M5 and M6 may be coupled to a single, shared, WL, the WL 250.

As also shown in FIG. 2, the input 222-1 of the first inverter 220-1 may be coupled to the first S/D terminal 214-6 of the access transistor M6, while the input 222-2 of the second inverter 220-2 may be coupled to the first S/D terminal 214-5 of the access transistor M5. In other words, each of the gate terminals 212-1 of the transistor M1 and the gate terminal 212-2 of the transistor M2 may be coupled to the first S/D terminal 214-6 of the access transistor M6, while each of the gate terminal 212-3 of the transistor M3 and the gate terminal 212-4 of the transistor M4 may be coupled to the first S/D terminal 214-5 of the access transistor M5. Phrased differently, each of the gate terminal 212-1 of the transistor M1 and the gate terminal 212-2 of the transistor M2 may be coupled to the second BL 240-2 (e.g., via the access transistor M6), while each of the gate terminal 212-3 of the transistor M3 and the gate terminal 212-4 of the transistor M4 may be coupled to the first BL 240-1 (e.g., via the access transistor M5).

The WL 250 and the first and second BLs 240 may be used together to read and program (i.e., write to) the SRAM cell 200. In particular, access to the cell may be enabled by the WL 250 which controls the two access transistors M5 and M6 which, in turn, control whether the cell 200 should be connected to the BLs 240-1 and 240-2. During operation of the SRAM cell 200, a signal on the first BL 240-1 may be complementary to a signal on the second BL 240-2. The two BLs 240 may be used to transfer data for both read and write operations. In other embodiments of the SRAM cell 200, only a single BL 240 may be used, instead of two BLs 240-1 and 240-2, although having one signal BL and one inverse, such as the two BLs 240, may help improve noise margins. During read accesses, the BLs 240 are actively driven high and low by the inverters 220-1, 220-2 in the SRAM cell 200.

Each of the WL 250 and the BLs 240, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

As mentioned briefly above, an SRAM circuit such as the SRAM memory cell 200 may be an example of CMOS circuitry in which NP boundary tuning may be performed. For example, NP boundary tuning may be employed to implement PMOS PU transistors, such as the transistors M2 and M4, that are weaker than the NMOS PD transistors M1 and M3.

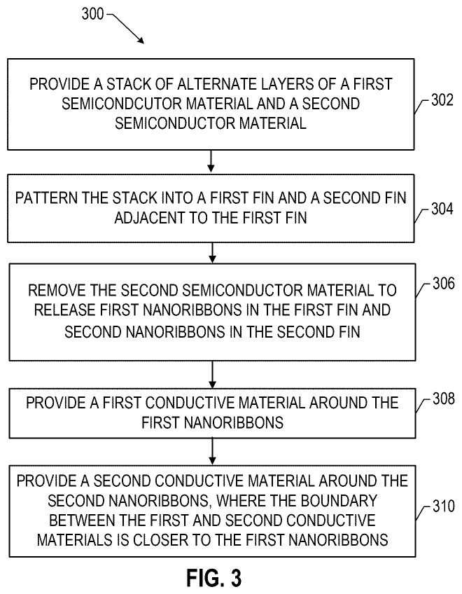

FIG. 3 is a flow diagram of an example method for fabricating an IC structure, where the method includes NP boundary tuning, in accordance with some embodiments.

Although the operations of the method of FIG. 3 are illustrated once each and in a particular order, the operations may be performed in any suitable order and repeated as desired. For example, one or more operations may be performed in parallel to fabricate multiple IC structures fabricated with NP boundary tuning techniques substantially simultaneously. In another example, the operations may be performed in a different order to reflect the structure of an IC device fabricated with NP boundary tuning techniques.

In addition, the example fabricating method of FIG. 3 may include other operations not specifically shown in FIG. 3, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 3 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

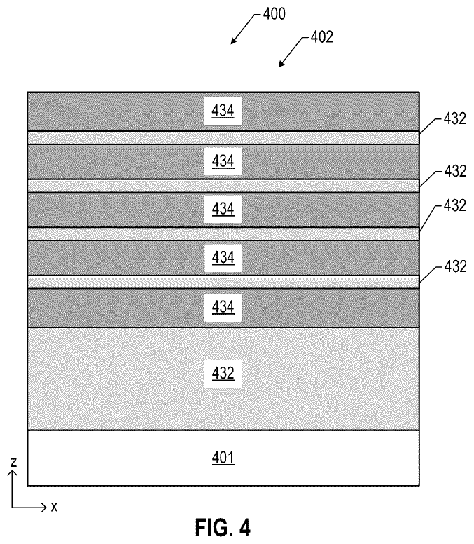

FIGS. 4-10 provide cross-sectional side views at various stages in the fabrication of an example IC structure according to the method of FIG. 3, in accordance with some embodiments.

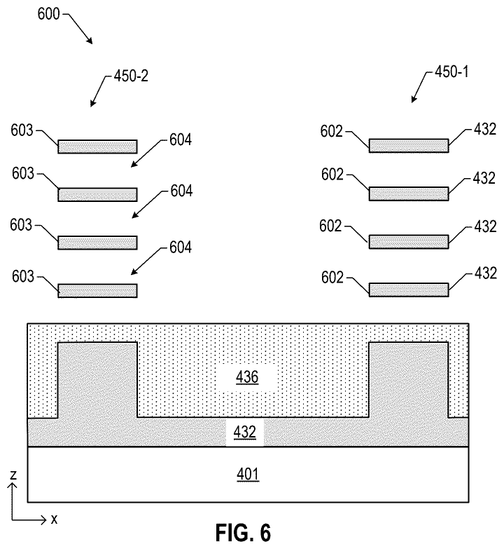

Turning to FIG. 3, the method 300 begins with a process 302 of providing a stack of alternate layers of a first semiconductor material and a second semiconductor material. The IC structure 400 of FIG. 4 is an example resulting IC structure of the process 302. The IC structure 400 includes a support 401 and alternating layers of a semiconductor 432 and layers of another material 434. While FIG. 4 illustrates five layers of the semiconductor material and four layers of the material 434 in a stack 402, in other embodiments, any other number of layers may be used as long as they are alternating and include at least three layers of the semiconductor material 432 and at least two layers of the material 434. The upper layers of the semiconductor material 432 will later be formed into nanoribbons stacked above one another, as shown in FIGS. 6-10, discussed below. Thus, although a particular number of nanoribbons formed of the upper layers of the semiconductor material 432 is depicted in FIG. 6 (namely, four nanoribbons) and subsequent drawings, embodiments of the present disclosure include IC structures having more or fewer stacked nanoribbons than depicted.

As shown in FIG. 4, in some embodiments, the alternation of layers of the semiconductor material 432 and the material 434 may begin after a bottom layer of the semiconductor material 432 is provided over the support 401. In one such example, the bottom layer of the semiconductor material 432 may later form a subfin under the stack of nanoribbons. Although the thickness of the bottom layer of the semiconductor material 432 is depicted as being greater than the subsequent layers of the semiconductor material 432 that are formed into nanoribbons via further processing, in other examples, the bottom layer of the semiconductor material 432 may have a substantially same thickness as another layer of the semiconductor material 432.

The semiconductor material 432 may be any of the semiconductor/channel materials described above with reference to the nanoribbon 104 of FIG. 1. The material 434 may be any suitable material that is etch-selective with respect to the semiconductor material 432 so that, in a later process, the material 434 may be etched away to form nanoribbons of the semiconductor material 432. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 432 may be silicon while the material 434 may be a second semiconductor material such as silicon germanium. In another example, the semiconductor material 432 may be silicon germanium, while the material 434 may be silicon. In other examples, the material 434 may be made of a non-semiconductor material, e.g., of an insulator material, as long as this material is sufficiently etch-selective with respect to the semiconductor material 432.

Thus, the material 434 may be any suitable sacrificial material that is etch-selective with respect to the semiconductor material 432. Selecting the material 434 to be a semiconductor material may be particularly advantageous because it may improve quality of the semiconductor material 432 if the semiconductor material 432 is epitaxially grown on the material 434. In some embodiments, the process 302 may include epitaxially growing layers of the semiconductor material 432 and the material 434 (e.g., a second semiconductor material) in an alternating manner. In other embodiments, alternate layers of the semiconductor material 432 and the material 434 may be provided in the process 302 using other techniques, such as layer transfer or thin-film deposition. Although FIG. 4 illustrates the same semiconductor material 432 in various layers of the IC structure 400, in general, material compositions of a semiconductor material from which nanoribbons will later be formed in different layers of the IC structure 400 may be different. For example, the semiconductor material 432 of one layer of the IC structure 400 may be silicon while the semiconductor material 432 of another layer of the IC structure 400 may be a III-N semiconductor material such as GaN.

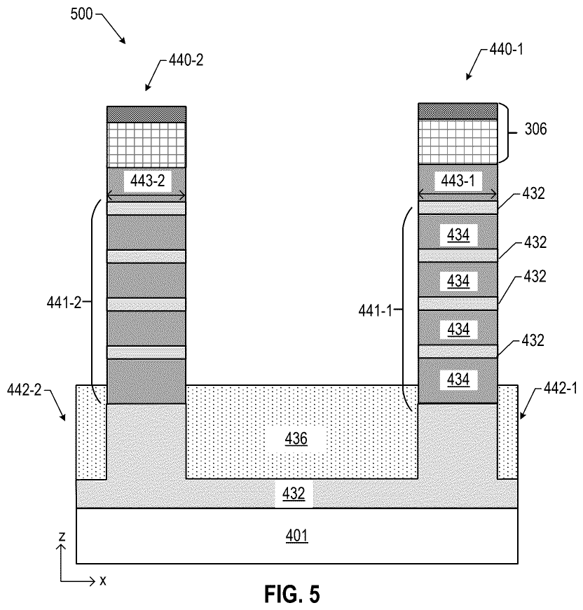

The method 300 continues with a process 304 of patterning the stack into fins. FIG. 5 illustrates an example of an IC structure 500 resulting from the process of forming fins from the stack of alternate layers of semiconductor material and another material. The IC structure 500 illustrates that the stack 402 of alternating layers of the semiconductor material 432 and the material 434, has been patterned into fins 440-1, 440-2. The fins 440-1, 440-2 may include active portions 441-1, 441-2 and subfin portions 442-1, 442-2. The active portions 441-1, 441-2 may be portions of the fins 440-1, 440-2 from which the respective nanoribbons will be formed, while the subfin portions 442-1, 442-2 are portions of the fins 440-1, 440-2 that have sidewalls at least partially enclosed with an insulator material 436, e.g., as shown in FIG. 5. The insulator material 436 may include any of insulator material typically used as a “shallow trench insulator” (STI) in fin-based or nanoribbon-based transistors, e.g., any suitable low-k dielectric material or other suitable insulator material.

Thus, each of the fins 440-1, 440-2 may be shaped as a structure that extends away from the support 401 and may include a subfin 442-1, 442-2 at the bottom, the subfin being a portion of the respective fin that is at least partially enclosed by an insulator material 436. In some embodiments, the subfins 442-1, 442-2 may include the bottom layer of the semiconductor material 432, as well as an upper portion of the support 401, as is shown in FIG. 5. However, in other embodiments, the subfins 442-1, 442-2 may include only the semiconductor material 432 and not any portions of the support 401 (not shown in the present drawings). In some embodiments, semiconductor material 432 of the subfins 442-2, 442-2 and/or the support 401 may be removed and/or replaced with one or more other materials in subsequent processes.

In some embodiments, the fins 440-1, 440-2 may have widths (i.e., a dimension of the fins 440-1, 440-2 measured along the x-axis of the example coordinate system shown in FIG. 5) that are substantially the same or different. For example, the fin 440-1 has a width 443-1 and the fin 440-2 has a width 443-2. The widths 443-1, 443-2 may be that of the width of the nanoribbons subsequently formed (e.g., the nanoribbon 104 of FIG. 1 described above). The fins 440-1, 440-2 may further have a length (i.e., a dimension of the fins 440-1, 440-2 measured along the y-axis of the example coordinate system shown in FIG. 4, where the y-axis is going into and coming out of the page) suitable to account for the length of the future nanoribbons (e.g., as described above with reference to the length of the nanoribbon 104 of FIG. 1). In some examples, one or more NMOS transistors will be formed in one of the fins 440-1, 440-2, and one or more PMOS transistors will be formed in the other of the fins 440-1, 440-2. In some example circuits in which the design calls for transistors in one of the fins 440-1, 440-2 to be weaker than transistors in the other of the fins 440-1, 440-2, the width of one of the fins may be smaller than the width of the other (e.g., the width 443-2 may be smaller than the width 443-1, or vice versa.

In various embodiments, any suitable patterning techniques may be used to form the fins 440-1, 440-2, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed to form the fins 440-1, 440-2 may include an anisotropic etch, using etchants in a form of e.g., chemically active ionized gas (i.e., plasma) using e.g., bromine (Br) and chloride (Cl) based chemistries. In some embodiments, during the etch to form the fins 440-1, 440-2, the IC structure may be heated to elevated temperatures, e.g., to temperatures between about room temperature and 200 degrees Celsius, including all values and ranges therein, to promote that byproducts of the etch are made sufficiently volatile to be removed from the surface.

The method 300 may continue with forming source and drain regions (S/D regions) in the fins. Forming S/D regions may involve, for example, forming S/D openings for the S/D regions in the fin, recessing a sacrificial material in the openings, providing a spacer material in the recessed areas, and providing an S/D material in the openings. The S/D regions are not visible in the cross-sectional views shown in FIGS. 5-9.

Referring again to FIG. 3, the method 300 continues with a process 306 of removing the second semiconductor material to release nanoribbons of the first semiconductor material. The IC structure 600 of FIG. 6 is an example resulting IC structure of the process 306. Removal of the second semiconductor material 434 may include any suitable etching technique. As a result of removing the material 434, a first stack 450-1 of nanoribbons 602 and a second stack 450-2 of nanoribbons 603 of the semiconductor material 432 are formed from the fins 440-1, 440-2, where adjacent nanoribbons of a stack (e.g., two adjacent nanoribbons 602 or two adjacent nanoribbons 603) are separated by openings 604. In the example illustrated in FIG. 6, there are four nanoribbons 602 in the stack 450-1 and four nanoribbons 603 in the stack 450-2. Thus, the nanoribbons 602 and 603 are “released” in that the openings 604 are formed around channel portions of the nanoribbons 602 and 603 of the semiconductor material 432. Thus, the nanoribbon stack 450-1 is adjacent (e.g., immediately neighboring) and substantially parallel to the nanoribbon stack 450-2, where two nanoribbon stacks may be adjacent if there is not an intervening nanoribbon stack between the adjacent nanoribbon stacks.

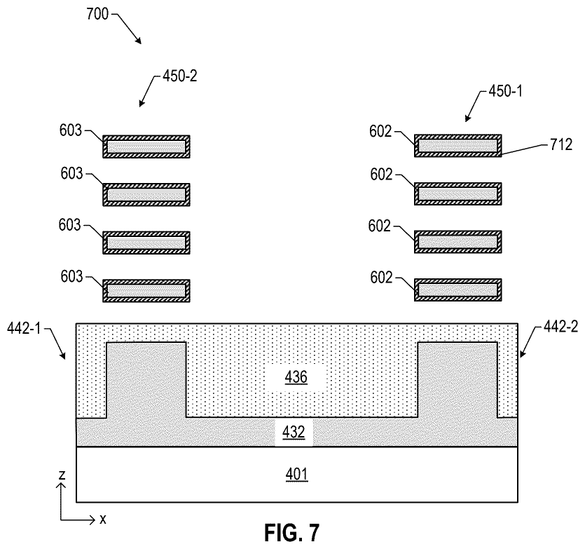

The method may continue with a process of providing a gate insulator material around gate regions of the nanoribbons of the stack. The IC structure 700 of FIG. 7 includes a gate insulator material 712 around the nanoribbons 602 and 603. The gate insulator material 712 may be an example of the gate insulator material 112. In some embodiments, the gate insulator material 712 may be absent in the IC structure 700.

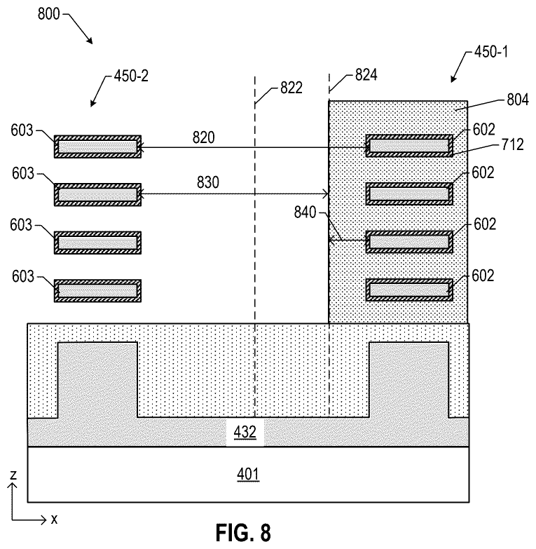

Referring again to FIG. 3, the method 300 continues with a process 308 of providing a conductive material (e.g., one or more gate electrode material(s)) around the first nanoribbons. As mentioned above, in some examples, NMOS and PMOS nanoribbon-based transistors may be formed with the same channel materials and different gate electrode materials (e.g., one or more different work function metals). FIG. 8 illustrates an example IC structure 800 resulting from the process of providing gate electrode materials around (e.g., at least partially around) portions of the nanoribbons for a PMOS transistor. In the example illustrated in FIG. 8, a conductive material 804 is deposited around portions of the nanoribbons 602 that are to form channel regions of a PMOS transistor. In one example, the conductive material 804 is a PMOS work function metal (e.g., a P-type work function metal suitable for PMOS devices). In one example, the conductive material 804 may include titanium and nitrogen (e.g., titanium nitride), tungsten, or another suitable conductive material for forming a gate electrode for a PMOS transistor. The conductive material 804 may be deposited according to any suitable deposition technique.

As can be seen in FIG. 8, the nanoribbon stack 450-1 and the nanoribbon stack 450-2 are separated by a distance 820 (e.g., where the distance is a measurement in a plane with a nanoribbon of the stacks 450-1 and/or 450-2, where the plane is substantially parallel with the substrate and nanoribbons). In some examples, the conductive material 804 may have been deposited such that about half the region between the stacks 450-1 and 450-2 would be filled with the conductive material 804, and another conductive material deposited around the nanoribbons 603 in a subsequent process could fill the remaining half region between the stacks 450-1, 450-2. In contrast, as can be seen in FIG. 8, less than half the region between the stacks 450-1 and 450-2 is filled with the conductive material 804. For example, the conductive material 804 may be deposited in a region between the stacks 450-1 and 450-2 up to a plane 824 that is at less than half the distance 820 between the stacks 450-1, 450-2 (as defined by the plane 822 that is about halfway between the stack 450-1 and the stack 450-2). The plane 824 may mark a boundary (e.g., NP boundary) between a P-type gate electrode material and an N-type gate electrode material that is deposited, where the term “NP boundary” as used herein refers to the boundary or interface between an N-type gate electrode material and a P-type gate electrode material between two adjacent nanoribbon stacks).

In some examples, the location of the NP boundary may be adjusted or “tuned” to achieve desired NMOS and PMOS transistor strengths. For example, by forming the NP boundary to be closer to the nanoribbons in which a PMOS transistor is formed (e.g., the nanoribbons 602), the resulting PMOS transistor may be made to be weaker than if the NP boundary was about half way between the two stacks 450-1, 450-2. In some examples, the strength of the transistors formed in the stack 450-1 may be made weaker with NP boundary tuning techniques without further reducing the width of the nanoribbons 602. Thus, in some examples, NP boundary tuning can enable formation of a weaker PMOS transistor in the stack 450-1 with a wider nanoribbon then may otherwise be achieved by changing the nanoribbon width alone. In one example, the ratio of the width 443-1 to the width 443-2 may be about 1:3 (e.g., in one example, the second width 443-2 may be about 2.9 to 3.1 times greater than the first width 443-1).

Referring again to FIG. 3, the method continues with the process 310 of providing a second conductive material around the second nanoribbons, where the boundary between the first and second conductive materials is closer to the first nanoribbons. FIG. 9 illustrates an example IC structure 900 resulting from the process 310. Specifically, the IC structure 900 of FIG. 9 illustrates a resulting IC structure after depositing a conductive material 902 around the nanoribbons 603. The conductive material 902 may be deposited with any suitable deposition technique, and may include an NMOS work function metal (e.g., an N-type work function metal suitable for NMOS devices). In one example, the conductive material 902 includes a metal carbide (e.g., includes one or more metals and carbon), tungsten, or another suitable conductive material. In the example illustrated in FIG. 9, the conductive material 902 fills more than half the region between the stacks 450-1 and 450-2. In some examples, the conductive material 804 is in contact with (e.g., in direct contact with such that there is no intervening material) the conductive material 902 at a boundary (e.g., at the plane 824) between the P-type gate electrode material (e.g., the conductive material 804) and the N-type gate electrode material (e.g., the conductive material 902). In the example illustrated in FIG. 9, a first transistor 903-1 may be formed in the stack 450-1 with a first channel region in portions of the nanoribbons 602 and a second transistor 903-2 may be formed in the stack 450-2 with a second channel region in portions of the nanoribbons 603. In one such example, the first transistor 903-1 includes the conductive material 804 at least partially around the first channel region, and the second transistor 903-2 includes the conductive material 902 at least partially around the second channel region. In one example, the conductive material 804 is in contact with the conductive material 902 between the first nanoribbon stack 450-1 and the second nanoribbon stack 450-2 at a first distance 840 from the first nanoribbon stack 450-1 and at a second distance 830 from the second nanoribbon stack 450-2, and where the second distance is greater than the first distance.

Although not specifically shown in FIGS. 4-9, the method may further involve forming S/D contact structures coupled with the S/D regions, and conductive interconnects (e.g., conductive vias) coupled with one or more of the S/D contact structures and/or gate contact structures of the transistors 903-1 and 903-2. Although FIG. 9 illustrates a single gate electrode material (e.g., the conductive material 804) around the nanoribbons 602 and a single gate electrode material (e.g., the conductive material 902) around the nanoribbons 603, in some examples, multiple conductive materials may be present around channel portions of the nanoribbons 602 and/or the nanoribbons 603.

FIG. 10 illustrates a cross-sectional view of an example IC structure 1000 with two gate electrode materials around the nanoribbons 602 and two gate electrode materials around the nanoribbons 603. As can be seen in FIG. 10, a first conductive material 1004 (which may be, for example, a first P-type gate electrode material including a first P-type work function metal) is deposited around channel portions of the nanoribbons 602. In one such example, the first conductive material 1004 may be in contact with the gate insulator material 712 around the nanoribbons 602. A second conductive material 804 (e.g., a second P-type gate electrode material including a second P-type work function metal) may then be deposited around the first conductive material 1004. Similarly, in the example illustrated in FIG. 10, a first conductive material 1002 (which may be, for example, a first N-type gate electrode material including a first N-type work function metal) is deposited around channel portions of the nanoribbons 603. In one such example, the first conductive material 1002 may be in contact with the gate insulator material 712 around the nanoribbons 603. A second conductive material 902 (e.g., a second N-type gate electrode material including a second N-type work function metal) may then be deposited around the first conductive material 1002. In other examples, one of the gate structures includes multiple (e.g., two or more than two) gate electrode materials around the nanoribbons and between the stacks, and another of the gate structures includes one gate electrode material around the nanoribbons and between the stacks 450-1, 450-2.

Thus, the method 300 is an example method of fabricating an IC structure, where the method includes NP tuning techniques. Performing the method 300 may result in features in the final IC structures that are characteristic of the use of the method 300. For example, one such feature is illustrated in the IC structure 900 shown in FIG. 9, in which the IC structure includes a first nanoribbon stack 450-1 including two or more first nanoribbons 602 of a semiconductor material 432 stacked over one another, a second nanoribbon stack 450-2 adjacent to the first nanoribbon stack 450-1, where the second nanoribbon stack 450-2 includes two or more second nanoribbons 603 of the semiconductor material 432 stacked over one another, a first gate electrode material 804 at least partially around the first nanoribbons 602, and a second gate electrode material 902 at least partially around the second nanoribbons 603, where the second gate electrode material 902 has a different material composition from the first gate electrode material 804, and where a boundary (e.g., at the plane 824) between the first gate electrode material 804 and the second gate electrode material 902 is closer to the first nanoribbon stack 450-1 than the second nanoribbon stack 450-2. In one example, the first gate electrode material includes a P-type work function metal, and the second gate electrode material comprises an N-type work function metal.

In one example, the first nanoribbon stack 450-1 is at a first distance 820 from the second nanoribbon stack 450-2, where the first distance 820 is a measurement in a plane substantially parallel to a nanoribbon 602 of the first nanoribbon stack 450-1 (and where the first distance 820 may be measured between the semiconductor material 432 of a nanoribbon 603 to the semiconductor material of a nanoribbon 602). In one such example, the boun0dary (e.g., at the plane 824) is a second distance 840 from the first nanoribbon stack 450-1, where the second distance 840 is about 5 to 30% of the first distance 820. In one example, the boundary (e.g., the plane 824) is a distance from the first nanoribbon stack 450-1 in a range of about 5 to 15 nanometers, or about 7 to 12 nanometers.

From another perspective, performing the method 300 may result in other such features, such as the gate structures of transistors in adjacent nanoribbon stacks having different widths in the regions between the stacks (e.g., asymmetric gate widths between the nanoribbon stacks). For example, referring to FIG. 9, the IC structure 900 includes a first gate structure 905-1 which includes the conductive material 804 and a second gate structure 905-2 which includes the conductive material 902. In one such example, a first portion 907-1 of the first gate structure 905-1 between the first nanoribbon stack 450-1 and the second nanoribbon stack 450-2 has a first width (e.g., as shown by the distance 840 in FIG. 9), where the first width is a first dimension of the first gate structure 905-1 in a plane with a nanoribbon 602 of the first nanoribbon stack 450-1, where the plane is substantially parallel to the nanoribbon. A second portion 907-2 of the second gate structure 905-2 between the first nanoribbon stack 450-1 and the second nanoribbon stack 450-2 has a second width (e.g., as shown by the distance 830), where the second width is a second dimension of the second gate structure 905-2 in the plane, and where the second width is about 2 to 10 times greater than the first width. In some examples, the first gate structure 905-1 and/or the second gate structure 905-2 may include additional conductive materials. For example, FIG. 10 illustrates an IC structure 1000 in which a first gate structure 1005-1 includes a further gate electrode material (e.g., the conductive material 1004) at least partially around the first nanoribbons 602, and a second gate structure 1005-2, which includes a further gate electrode material (e.g., the conductive material 1002) at least partially around the second nanoribbons 603. In one such example, the conductive material 804 is between the conductive material 1004 and the conductive material 902, and the conductive material 902 is between the conductive material 1002 and the conductive material 804.

Another such feature can be seen in FIG. 9, where the conductive material 804 is in contact with the conductive material 902 between the first nanoribbon stack 450-1 and the second nanoribbon stack 450-2 at a first distance 840 from the first nanoribbon stack 450-1 and at a second distance 830 from the second nanoribbon stack 450-2, where the second distance 830 is greater than the first distance 840 (e.g., the first distance may be about 10-50% the second distance).

The transistors in the IC structures 900 and 1000 may be included in any CMOS circuit, such as the SRAM memory cell circuit discussed above with respect to FIG. 2. For example, a memory cell may include the first transistor 903-1 and the second transistor 903-2. In one such example, the transistors 903-1 and 903-2 may include gate structures or terminals and one S/D region or terminal each (e.g., drain regions) that are coupled together. For example, the first transistor 903-1 may include a first source region and a first drain region, the second transistor 903-2 may include a second source region and a second drain region, where one of the first source region and first drain region is coupled with one of the second source region and the second drain region. In one such example, another of the first source region and the first drain region may coupled with a first conductive interconnect to be coupled with ground, and another of the second source region and the second drain region is coupled with a second conductive interconnect to be coupled with a power source (e.g., such as transistors M1 and M2 of FIG. 2).

Although some examples referred to forming the NP boundary to be closer to the nanoribbons in which a PMOS transistor is formed, in other examples, the NP boundary can be formed to be closer to nanoribbons in which an NMOS transistor is formed. Also, although some examples referred to forming a PMOS gate structure before an NMOS gate structure around an adjacent nanoribbon stack, in other examples, the process order may be reversed (e.g., an NMOS gate structure may be formed prior to a PMOS gate structure around an adjacent nanoribbon stack). Furthermore, although examples described herein refer to nanoribbon-based transistors, NP boundary tuning techniques may apply to other transistor architectures.

IC structures fabricated with NP boundary tuning techniques as described herein (e.g., as described with reference to FIGS. 1-10) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures disclosed herein, e.g., the IC structures 900 and 1000, may be included in any suitable electronic component. FIGS. 11-15 illustrate various examples of apparatuses that may include the IC structures 900 and 1000 disclosed herein.

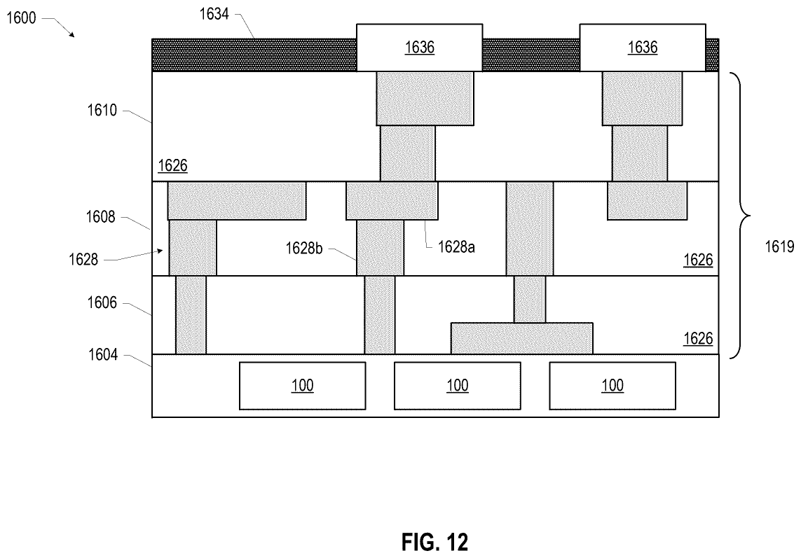

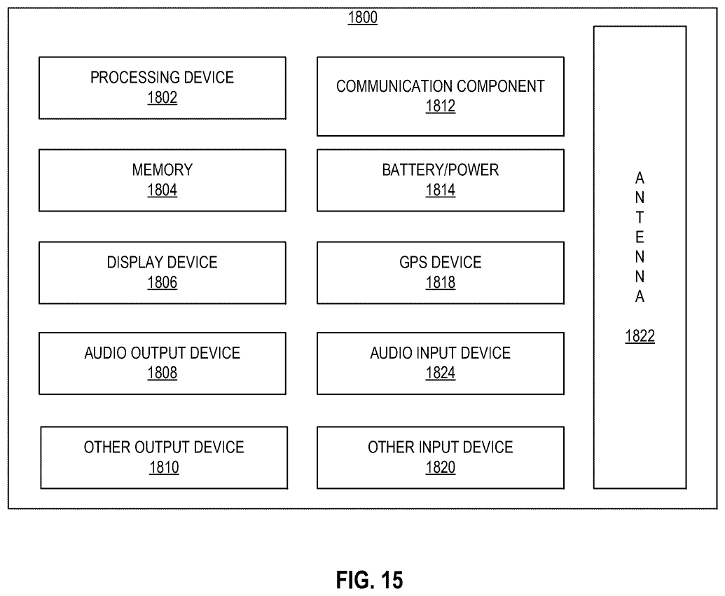

FIG. 11 is a top view of a wafer 1500 and dies 1502 that may include one or more IC structures 900 and 1000 in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures 900 and 1000 (e.g., as discussed below with reference to FIG. 12), one or more transistors (e.g., some of the transistors of the device region 1604 of FIG. 12, discussed below, e.g., nanoribbon-based transistors of the IC structures 900 and 1000) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 15) or other logic that is configured to store information in the memory devices or execute instructions stored in the memory array.

FIG. 12 is a side, cross-sectional view of an IC device 1600 that may include one or more IC structures in accordance with any of the embodiments disclosed herein (e.g., in accordance with IC structures 900 and 1000). One or more of the IC devices 1600 may be included in one or more dies 1502 (FIG. 11). The IC device 1600 may include a device region 1604 including one or more IC structures (e.g., one or more of IC structures 900 and 1000) disclosed herein, or any variations of the IC structures. The device region 1604 may further include electrical contacts to the gates of the transistors included in the device region 1604 and to the S/D materials of the transistors included in the device region 1604 (e.g., to the S/D regions 114 of the IC structure 100).

Electrical signals, such as power and/or input/output (I/O) signals, may be routed to and/or from the devices (e.g., the transistors) of the device region 1604 through one or more interconnect layers disposed on the device region 1604 (illustrated in FIG. 12 as interconnect layers 1606-1610). For example, electrically conductive features of the device region 1604 (e.g., the gate electrode material 108 of the IC structure 100) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 12). Although a particular number of interconnect layers 1606-1610 is depicted in FIG. 12, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support 102 upon which the device region 1604 is formed. For example, the lines 1628a may route electrical signals in a direction in and out of the page from the perspective of FIG. 12. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 12. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structure 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606-1610. In FIG. 12, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

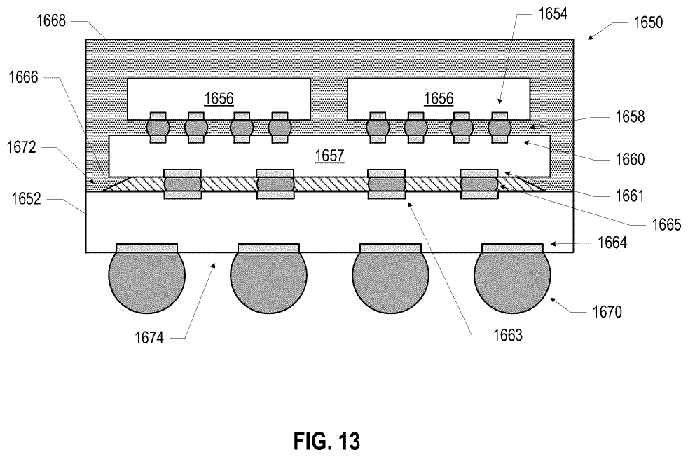

FIG. 13 is a side, cross-sectional view of an example IC package 1650 that may include one or more IC structures 900 and 1000 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 12.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 13 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 13 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

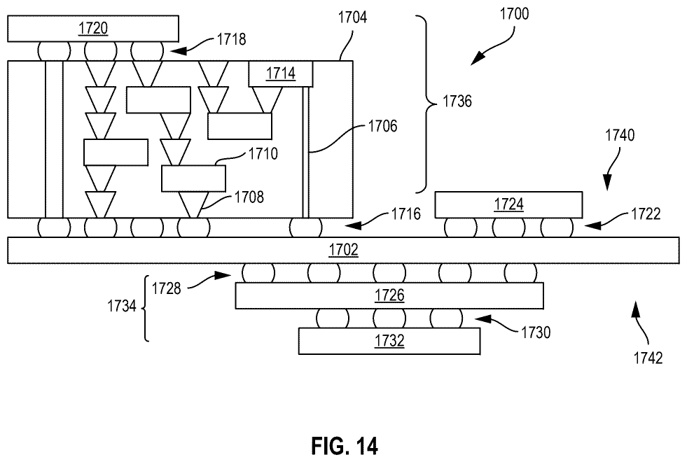

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 13 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 14.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 13 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 13, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 14 is a side, cross-sectional view of an IC device assembly 1700 that may include one or more IC packages or other electronic components (e.g., a die) including one or more IC structures 900 and 1000 in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 13 (e.g., may include one or more IC structures 900 and 1000).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 14 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 14), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 14, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device (e.g., the IC device 1600 of FIG. 12), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 14, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 14 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 15 is a block diagram of an example electrical device 1800 that may include one or more IC structures 900 and 1000 in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 15 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 15, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a first nanoribbon stack including two or more first nanoribbons of a semiconductor material stacked over one another; a second nanoribbon stack (e.g., adjacent to) the first nanoribbon stack, where the second nanoribbon stack includes two or more second nanoribbons of the semiconductor material stacked over one another; a first gate electrode material at least partially around the first nanoribbons; and a second gate electrode material at least partially around the second nanoribbons, where: the second gate electrode material has a different material composition from the first gate electrode material, and a boundary between the first gate electrode material and the second gate electrode material is closer to the first nanoribbon stack than the second nanoribbon stack.

Example 2 provides the IC structure of example 1, where: the first nanoribbon stack is at a first distance from the second nanoribbon stack, where the first distance is a measurement in a plane substantially parallel to a nanoribbon of the first nanoribbon stack, the boundary is a second distance from the first nanoribbon stack, and the second distance is about 5 to 30% of the first distance (e.g., the distance of the NP boundary to the PMOS nanoribbons is about 5-30% the total distance between nanoribbon stacks).

Example 3 provides the IC structure of any one of examples 1-2, where: the boundary is at a distance from the first nanoribbon stack in a range of about 5 to 15 nanometers.

Example 4 provides the IC structure of any one of examples 1-3, where: the first gate electrode material is in contact with the second gate electrode material at the boundary.

Example 5 provides the IC structure of any one of examples 1-4, where: the first gate electrode material includes a P-type work function metal, and the second gate electrode material includes an N-type work function metal.

Example 6 provides the IC structure of any one of examples 1-5, further including a first gate structure including the first gate electrode material; and a second gate structure including the second gate electrode material, where: a first portion of the first gate structure between the first nanoribbon stack and the second nanoribbon stack has a first width, the first width is a first dimension of the first gate structure in a plane with a nanoribbon of the first nanoribbon stack, where the plane is substantially parallel to the nanoribbon, a second portion of the second gate structure between the first nanoribbon stack and the second nanoribbon stack has a second width, the second width is a second dimension of the second gate structure in the plane, and the second width is about 2 to 10 times greater than the first width.

Example 7 provides the IC structure of example 6, where: the second gate structure includes a third gate electrode material at least partially around the second nanoribbons, and the second gate electrode material is between the first gate electrode material and the third gate electrode material.

Example 8 provides the IC structure of any one of examples 1-7, where: a first nanoribbon of the first two or more nanoribbons has a first width, a second nanoribbon of the second two or more nanoribbons has a second width, and the second width is about 2.9 to 3.1 times the first width.

Example 9 provides an IC structure, including a first transistor with a first channel region in a first portion of a first nanoribbon stack; and a second transistor with a second channel region in a second portion of a second nanoribbon stack adjacent to the first nanoribbon stack, where: the first transistor includes a first conductive material at least partially around the first channel region, the second transistor includes a second conductive material at least partially around the second channel region, the first conductive material is in contact with the second conductive material between the first nanoribbon stack and the second nanoribbon stack at a first distance from the first nanoribbon stack and at a second distance from the second nanoribbon stack, and the second distance is greater than the first distance.

Example 10 provides the IC structure of example 9, where: one of the first conductive material and the second conductive material includes an N-type work function metal and another of the first conductive material and the second conductive material includes a P-type work function metal.

Example 11 provides the IC structure of any one of examples 9-10, where: the first distance is about 10-50% the second distance.

Example 12 provides the IC structure of any one of examples 9-11, including a memory cell including the first transistor and the second transistor.

Example 13 provides the IC structure of any one of examples 9-12, where: the first transistor includes a first source region and a first drain region, the second transistor includes a second source region and a second drain region, and one of the first source region and first drain region is coupled with one of the second source region and the second drain region.

Example 14 provides the IC structure of example 13, where: another of the first source region and the first drain region is coupled with a first conductive interconnect to be coupled with ground, and another of the second source region and the second drain region is coupled with a second conductive interconnect to be coupled with a power source.

Example 15 provides the IC structure of any one of examples 9-14, further including a third conductive material between the first conductive material and the first channel region.

Example 16 provides the IC structure of example 15, further including a fourth conductive material between the second conductive material and the second channel region.

Example 17 provides an IC structure, including a first transistor over a substrate, the first transistor including a first channel region, a first source region, a first drain region, and a first gate structure coupled with the first channel region, where the first gate structure includes a P-type work function metal; and a second transistor over the substrate, the second transistor including a second channel region, a second source region, a second drain region, and a second gate structure coupled with the second channel region, where the second gate structure includes an N-type work function metal, where: the first drain region is coupled with the second drain region, the first gate structure is coupled with the second gate structure, the first gate structure has a first width between the first transistor and the second transistor in a plane with the first channel region, where the plane is substantially parallel with the substrate, the second gate structure has a second width between the first transistor and the second transistor in the plane, and the second width is greater than the first width.

Example 18 provides the IC structure of example 17, where: the first source region of the first transistor is coupled with a first conductive interconnect, the second source region of the second transistor is coupled with a second conductive interconnect, the first conductive interconnect is to be coupled with a voltage source, and the second conductive interconnect is to be coupled with ground.

Example 19 provides the IC structure of any one of examples 17-18, where: the first transistor includes a pull-up transistor of an inverter circuit, and the second transistor includes a pull-down transistor of the inverter circuit.

Example 20 provides the IC structure of any one of examples 17-19, further including an SRAM memory cell including the first transistor and the second transistor, where: the SRAM memory cell includes a third transistor, the third transistor includes a third channel region, a third source region, a third drain region, and a third gate structure coupled with the third channel region, where the third gate structure includes the N-type work function metal, and one of the third source region and third drain region is coupled with the first gate structure and the second gate structure.

Example 21 provides the IC structure of any one of examples 17-20, where: the second width is about 4 to 9 times greater than the first width.

Example 22 provides the IC structure of any one of examples 17-21, where: the first channel region includes a first portion of a first nanoribbon of a first nanoribbon stack, the second channel region includes a second portion of a second nanoribbon of a second nanoribbon stack adjacent to the first nanoribbon stack, and one or more of the first nanoribbon and the second nanoribbon are in the plane.

Example 23 provides an IC structure according to any one of examples 1-22, where the IC structure includes or is a part of a central processing unit.

Example 24 provides an IC structure according to any one of examples 1-23, where the IC structure includes or is a part of a memory device.

Example 25 provides an IC structure according to any one of examples 1-24, where the IC structure includes or is a part of a logic circuit.

Example 26 provides an IC structure according to any one of examples 1-25, where the IC structure includes or is a part of input/output circuitry.

Example 27 provides an IC structure according to any one of examples 1-26, where the IC structure includes or is a part of a FPGA transceiver.

Example 28 provides an IC structure according to any one of examples 1-27, where the IC structure includes or is a part of a FPGA logic.

Example 29 provides an IC structure according to any one of examples 1-28, where the IC structure includes or is a part of a power delivery circuitry.

Example 30 provides an IC package that includes an IC die including an IC structure according to any one of examples 1-29; and a further IC component, coupled to the IC die.

Example 31 provides an IC package according to example 30 where the further IC component includes a package substrate.

Example 32 provides an IC package according to example 30, where the further IC component includes an interposer.

Example 33 provides an IC package according to example 30, where the further IC component includes a further IC die.

Example 34 provides a computing device that includes a carrier substrate and an IC structure coupled to the carrier substrate, where the IC structure is an IC structure according to any one of examples 1-29, or the IC structure is included in the IC package according to any one of examples 30-33.

Example 35 provides a computing device according to example 34, where the computing device is a wearable or handheld computing device.

Example 36 provides a computing device according to examples 34 or 35, where the computing device further includes one or more communication chips.

Example 37 provides a computing device according to any one of examples 34-36, where the computing device further includes an antenna.

Example 38 provides a computing device according to any one of examples 34-37, where the carrier substrate is a motherboard.

Example 39 provides a method of fabricating an IC structure, the method including providing a stack of alternate layers of a semiconductor material and a further material; patterning the stack into a first fin and a second fin adjacent to the first fin; removing the further material to release first nanoribbons of the semiconductor material in the first fin and second nanoribbons of the semiconductor material in the second fin; providing a first conductive material around the first nanoribbons; and providing a second conductive material around the second nanoribbons, where a boundary between the first conductive material and the second conductive material is closer to the first nanoribbons than the second nanoribbons.

Example 40 provides the method of example 39, further including; providing a gate dielectric material around the first nanoribbons and the second nanoribbons.

Example 41 provides a method according to any one of examples 39-40, where the IC structure is an IC structure according to any one of the preceding examples.

Example 42 provides a process of making an IC structure according to the method of any one of examples 39-41.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first nanoribbon stack comprising two or more first nanoribbons of a semiconductor material stacked over one another;
a second nanoribbon stack the first nanoribbon stack, wherein the second nanoribbon stack comprises two or more second nanoribbons of the semiconductor material stacked over one another;
a first gate electrode material at least partially around the first nanoribbons; and
a second gate electrode material at least partially around the second nanoribbons, wherein:
the second gate electrode material has a different material composition from the first gate electrode material, and
a boundary between the first gate electrode material and the second gate electrode material is closer to the first nanoribbon stack than the second nanoribbon stack.

2. The IC structure of claim 1, wherein:
the first nanoribbon stack is at a first distance from the second nanoribbon stack, wherein the first distance is a measurement in a plane substantially parallel to a nanoribbon of the first nanoribbon stack,
the boundary is a second distance from the first nanoribbon stack, and
the second distance is about 5 to 30% of the first distance.

3. The IC structure of claim 1, wherein:
the boundary is at a distance from the first nanoribbon stack in a range of about 5 to 15 nanometers.

4. The IC structure of claim 1, wherein:
the first gate electrode material is in contact with the second gate electrode material at the boundary.

5. The IC structure of claim 1, wherein:
the first gate electrode material comprises a P-type work function metal, and the second gate electrode material comprises an N-type work function metal.

6. The IC structure of claim 1, further comprising:
a first gate structure comprising the first gate electrode material; and
a second gate structure comprising the second gate electrode material, wherein:
a first portion of the first gate structure between the first nanoribbon stack and the second nanoribbon stack has a first width,
the first width is a first dimension of the first gate structure in a plane with a nanoribbon of the first nanoribbon stack, wherein the plane is substantially parallel to the nanoribbon, a second portion of the second gate structure between the first nanoribbon stack and the second nanoribbon stack has a second width,
the second width is a second dimension of the second gate structure in the plane, and
the second width is about 2 to 10 times greater than the first width.

7. The IC structure of claim 6, wherein:
the second gate structure comprises a third gate electrode material at least partially around the second nanoribbons, and
the second gate electrode material is between the first gate electrode material and the third gate electrode material.

8. The IC structure of claim 1, wherein:
a first nanoribbon of the first two or more nanoribbons has a first width,
a second nanoribbon of the second two or more nanoribbons has a second width, and
the second width is about 2.9 to 3.1 times the first width.

9. An integrated circuit (IC) structure, comprising:
a first transistor with a first channel region in a first portion of a first nanoribbon stack; and
a second transistor with a second channel region in a second portion of a second nanoribbon stack adjacent to the first nanoribbon stack, wherein:
the first transistor comprises a first conductive material at least partially around the first channel region,
the second transistor comprises a second conductive material at least partially around the second channel region,
the first conductive material is in contact with the second conductive material between the first nanoribbon stack and the second nanoribbon stack at a first distance from the first nanoribbon stack and at a second distance from the second nanoribbon stack, and
the second distance is greater than the first distance.

10. The IC structure of claim 9, wherein:
one of the first conductive material and the second conductive material comprises an N-type work function metal and another of the first conductive material and the second conductive material comprises a P-type work function metal.

11. The IC structure of claim 9, wherein:
the first distance is about 10-50% the second distance.

12. The IC structure of claim 9, comprising:
a memory cell comprising the first transistor and the second transistor.

13. The IC structure of claim 9, wherein:
the first transistor comprises a first source region and a first drain region, the second transistor comprises a second source region and a second drain region, and
one of the first source region and first drain region is coupled with one of the second source region and the second drain region.

14. The IC structure of claim 13, wherein:
another of the first source region and the first drain region is coupled with a first conductive interconnect to be coupled with ground, and
another of the second source region and the second drain region is coupled with a second conductive interconnect to be coupled with a power source.

15. The IC structure of claim 9, further comprising:
a third conductive material between the first conductive material and the first channel region.

16. The IC structure of claim 15, further comprising:
a fourth conductive material between the second conductive material and the second channel region.

17. An integrated circuit (IC) structure, comprising:
a first transistor over a substrate, the first transistor comprising:
a first channel region, a first source region, a first drain region, and a first gate structure coupled with the first channel region, wherein the first gate structure comprises a P-type work function metal; and
a second transistor over the substrate, the second transistor comprising:
a second channel region, a second source region, a second drain region, and a second gate structure coupled with the second channel region, wherein the second gate structure comprises an N-type work function metal, wherein:
the first drain region is coupled with the second drain region,
the first gate structure is coupled with the second gate structure,
the first gate structure has a first width between the first transistor and the second transistor in a plane with the first channel region, wherein the plane is substantially parallel with the substrate,
the second gate structure has a second width between the first transistor and the second transistor in the plane, and
the second width is greater than the first width.

18. The IC structure of claim 17, wherein:
the first source region of the first transistor is coupled with a first conductive interconnect,
the second source region of the second transistor is coupled with a second conductive interconnect,
the first conductive interconnect is to be coupled with a voltage source, and
the second conductive interconnect is to be coupled with ground.

19. The IC structure of claim 17, wherein:
the first transistor comprises a pull-up transistor of an inverter circuit, and
the second transistor comprises a pull-down transistor of the inverter circuit.

20. The IC structure of claim 17, further comprising:
an SRAM memory cell comprising the first transistor and the second transistor, wherein:
the SRAM memory cell comprises a third transistor,
the third transistor comprises a third channel region, a third source region, a third drain region, and a third gate structure coupled with the third channel region, wherein the third gate structure comprises the N-type work function metal, and
one of the third source region and third drain region is coupled with the first gate structure and the second gate structure.
